(19) United States
(12) Patent Application Publication
(10) Pub. No.: US 2021/0376127 A1
(43) Pub. Date: Dec. 2, 2021

(54) METHOD FOR PRODUCING SEMICONDUCTOR DEVICE

(71) Applicant: TOYODA GOSEI CO., LTD., Kiyosu-shi (JP)

(72) Inventors: Toru OKA, Kiyosu-shi (JP); Yukihisa UENO, Kiyosu-shi (JP)

(21) Appl. No.: 17/241,827

(22) Filed: Apr. 27, 2021

(30) Foreign Application Priority Data
May 29, 2020 (JP) 2020-095132

(51) Int. Cl. H01L 29/66; H01L 29/20; H01L 29/24; H01L 29/06

(52) U.S. Cl. CPC H01L 29/66734; H01L 29/0607; H01L 29/24; H01L 29/2003

(57) ABSTRACT

The present invention provides a method for producing a semiconductor device in which the on-resistance can be reduced while increasing the threshold voltage. A first n-type layer, a first p-type layer, a second p-type layer, and a second n-type layer are sequentially deposited through MOCVD on a substrate. The second p-type layer has a Mg concentration higher than the Mg concentration of the first p-type layer and not less than 6×10¹⁸/cm³. By setting the Mg concentration in this way, the threshold voltage is almost determined by the Mg concentration of the second p-type layer, and the threshold voltage does not depend on the Mg concentration of the first p-type layer. Therefore, channel resistance, that is, on-resistance is reduced by setting the Mg concentration of the first p-type layer to less than 6×10¹⁸/cm³.

### BACKGROUND OF THE INVENTION

### Field of the Invention

The present invention relates to a method for producing a Group III nitride semiconductor device or a gallium oxide-based semiconductor device.

### Background Art

As a field effect transistor (FET), a trench gate structure is known, in which a trench passing through a body layer and reaching a drift layer is formed, a gate insulating film is formed so as to cover a bottom surface and a side surface of the trench, and a gate electrode is formed on the gate insulating film on the bottom surface and the side surface of the trench (refer to Japanese Patent Application Laid-Open (kokai) No. 2009-117820). For GaN, a p-type region is difficult to be formed by ion implantation. Therefore, a GaN-based FET generally has a trench structure in which a p-type region is formed in an epitaxially growing layer structure and a trench is formed by dry etching. For Ga₂O₃ as well, a p-type region is difficult to be formed by ion implantation, and an FET needs to have the same structure as in the GaN based FET.

However, when a trench is formed by dry etching, etching damage is caused on the side surface of the trench exposed by etching. Etching damage reduces the acceptor concentration of the exposed side surface. This causes a problem of reduction in threshold voltage of the gate channel formed on the side surface of the trench.

The threshold voltage can be increased by increasing the acceptor concentration of the body layer. However, when the acceptor concentration of the body layer is increased, channel mobility is reduced, and channel resistance is increased. That is, on-resistance is increased.

### SUMMARY OF THE INVENTION

In view of the foregoing, an object of the present invention is to achieve a method for producing a semiconductor device in which the on-resistance can be reduced while increasing the threshold voltage.

In an aspect of the present invention, there is provided a method for producing a semiconductor device as a transistor with a trench gate structure, having a semiconductor layer comprising Group III nitride semiconductor or gallium oxide-based semiconductor formed by sequentially deposing a first n-type layer, a p-type layer, and a second n-type layer, wherein the p-type layer has a plurality of layers, the layer having the highest acceptor concentration of those layers is defined as a high concentration layer, the high concentration layer has an acceptor concentration of not less than. 6×10¹⁸/cm³, the layers other than the high concentration layer of a plurality of layers of the p-type layer has an acceptor concentration of less than 6×10¹⁸/cm³, and the threshold voltage is controlled to a desired value by the acceptor concentration of the high concentration layer.

In the present invention, the threshold voltage is increased while suppressing the increase of the on-resistance by increasing the acceptor concentration at a part of the longitudinal direction of the channel compared with other channel region. Therefore, the high concentration layer preferably has a higher acceptor concentration and a smaller thickness.

In the aspect of the present invention, the high concentration layer preferably has a thickness of 0.05 μm to 0.2 μm. The high concentration layer preferably has an acceptor concentration of not more than 1×10²⁰/cm³. The high concentration layer preferably has an acceptor concentration of not less than 6×10¹⁸/cm³, more preferably 6×10¹⁸/cm³ to 1×10²⁰/cm³.

The total thickness of the layers other than the high concentration layer of a plurality of layers of the p-type layer is preferably 0.5 μm to 1.5 μm. The high concentration layer may be the top layer or the bottom layer of the p-type layer. The p-type layer may further have a layer in contact with the first n-type layer and having an acceptor concentration higher than the acceptor concentration of the layers other than the high concentration layer and not more than 6×10¹⁸/cm³.

In the present invention, the p-type layer has a plurality of layers having different acceptor concentrations, the highest acceptor concentration of those layers is not less than 6×10¹⁸/cm³, and the acceptor concentration of the layers other than the high concentration layer of the p-type layer is less than 6×10¹⁸/cm³. Therefore, the channel resistance can be reduced while increasing the threshold voltage, that is, on-resistance can be reduced.

### BRIEF DESCRIPTION OF THE DRAWINGS

Various other objects, features, and many of the attendant advantages of the present techniques will be readily appreciated as the same becomes better understood with reference to the following detailed description of the preferred embodiments when considered in connection with the accompanying drawings, in which:

FIG. 1 shows the structure of a semiconductor device according to a first embodiment;

FIG. 2 shows the structure of a semiconductor device according to a variation;

FIGS. 3A to 3D are sketches showing processes for producing the semiconductor device according to the first embodiment;

FIG. 4 is a sketch showing processes for producing a semiconductor device according to a second embodiment;

FIG. 5 shows the structure of a semiconductor device according to a variation;

FIG. 6 shows the structure of a semiconductor device according to a variation;

FIG. 7 shows the structure of a semiconductor device according to a third embodiment;

FIG. 8 shows the structure of a semiconductor device according to a variation;

FIG. 9 is a graph showing Id-Vg characteristic of semiconductor devices of Examples 1 to 3 and Comparative Examples 1 to 3;

FIG. 10 is a graph showing Id-Vg characteristic of semiconductor devices of Examples 1 to 3 and Comparative Examples 1 to 3;

FIG. 11 is a comparison table showing characteristics of semiconductor devices of Examples 1 to 3 and Comparative Examples 1 to 3.

### DETAILED DESCRIPTION OF PREFERRED EMBODIMENTS

Specific embodiments of the present invention will next be described with reference to the drawings. However, the present invention is not limited to the embodiments.

### First Embodiment

FIG. 1 shows the structure of a semiconductor device according to a first embodiment. As shown in FIG. 1, the semiconductor device according to the first embodiment is a vertical MISFET having a trench gate structure, which includes a substrate 110, a first n-type layer 120, a p-type layer 130, a second n-type layer 140, a trench T1, a recess R1, a gate insulating film F1, a gate electrode G1, a source electrode S1, a body electrode B1, and a drain electrode D1.

The substrate 110 is a flat plate-shaped substrate made of Si-doped n-GaN having a c-plane main surface. The substrate 110 has a thickness of, for example, 300 μm and a Si concentration of, for example, 1×10¹⁸/cm³. Any conductive material other than n-GaN may be used as a substrate for growing Group III nitride semiconductor. For example, ZnO or Si may be used. However, in terms of lattice matching, a GaN substrate is preferably used as in the present embodiment. Si is used as an n-type impurity in the first embodiment. However, any element other than Si, for example, Ge or O may be used.

The first n-type layer 120 is a Si-doped n-GaN layer deposited on the substrate 110. The first n-type layer 120 has a thickness of, for example, 10 μm, and a Si concentration of, for example, 8×10¹⁵/cm³.

The p-type layer 130 is a Mg-doped p-GaN layer deposited on the first n-type layer 120. The p-type layer 130 has a two-layer structure in which a first p-type layer 131 and a second p-type layer 132 are sequentially deposited. In the first embodiment, Mg is used as a p-type impurity. However, any element other than Mg, for example, Be or Zn may be used.

The first p-type layer 131 has a Mg concentration lower than the Mg concentration of the second p-type layer 132. The first p-type layer 131 has a thickness of, for example, 0.55 μm, and a Mg concentration of, for example, 2×10¹⁸/cm³. The first p-type layer may have a thickness of 0.5 μm to 1.5 μm. By reducing the Mg concentration of the first p-type layer 131 of a plurality of layers constituting the p-type layer 130, the reduction of channel mobility can be suppressed, and the increase of on-resistance can be suppressed. Because the channel is mainly formed in the first p-type layer 131 which is thicker than the second p-type layer 132, the channel mobility is kept to be higher and the on-resistance is kept to be lower.

The first p-type layer 131 may have any Mg concentration as long as it is less than 6×10¹⁸/cm³. However, the first p-type layer 131 preferably has a Mg concentration of not more than 3×10¹⁸/cm³, thereby further reducing the on-resistance.

The second p-type layer 132 has a Mg concentration higher than the Mg concentration of the first p-type layer 131. The second p-type layer 132 is provided to increase the threshold voltage. The second p-type layer 132 has a thickness of, for example, 0.15 μm, and a Mg concentration of, for example, 1×10¹⁹/cm³.

The details of the reason why the p-type layer 130 has a two-layer structure of the first p-type layer 131 and the second p-type layer 132 are as follows.

In an FET, the threshold voltage is determined by the Mg concentration of the p-type layer 130 as a body layer. In a vertical FET having a GaN semiconductor layer, like the semiconductor device according to the first embodiment, a p-type region, i.e., body layer is difficult to be formed by ion implantation. Therefore, in the semiconductor device according to the first embodiment, after a layer structure including the p-type layer 130 is deposited by crystal growth, a trench T1 is formed by dry etching to form a trench gate structure.

However, when the trench T1 is formed by dry etching, etching damage is caused on the bottom surface and the side surface of the trench T1, thereby reducing the acceptor concentration. As a result, the threshold voltage, i.e., gate turn-on voltage, is reduced.

In the first embodiment, the p-type layer 130 comprises two layers, and one (second p-type layer 132) of the layers has a Mg concentration of not less than 6×10¹⁸/cm³. By setting the Mg concentration in this way, the threshold voltage is almost determined by the Mg concentration of the second p-type layer 132 having a higher acceptor concentration, and the threshold voltage does not depend on the Mg concentration of the first p-type layer 131. By setting the Mg concentration of the first p-type layer 131 to less than 6×10¹⁸/cm³, on-resistance is reduced.

In the semiconductor device according to the first embodiment, the recess R1 is formed by dry etching. This causes etching damage, thereby increasing the contact resistance between the p-type layer 130 and the body electrode B1. However, the contact resistance of the body electrode B1 is reduced by increasing the Mg concentration of the second p-type layer 132 in contact with the bottom surface of the body electrode B1. When the contact resistance is reduced, holes generated in the p-type layer 130 can be efficiently extracted, and avalanche breakdown voltage can be increased.

The Mg concentration of the second p-type layer 132 is not limited to the above value, and may be not less than 6×10¹⁸/cm³, preferably not more than 1×10²⁰/cm³. As long as the second p-type layer 132 has a Mg concentration of not less than 6×10¹⁸/cm³, the threshold voltage is not affected even if the first p-type layer 131 has a Mg concentration of less than 6×10¹⁸/cm³. The threshold voltage can almost be determined by the Mg concentration of the second p-type layer 132 having a higher acceptor concentration, and the threshold voltage can be increased. Therefore, normally off operation can be more reliably achieved. However, the second p-type layer 132 preferably has a Mg concentration of not more than 1×10²⁰/cm³. Deterioration in crystal quality or reduction in electron concentration of the second n-type layer 140 formed on the second p-type layer 132 can be suppressed. The Mg concentration of the second p-type layer 132 is more preferably 8×10¹⁸/cm³ to 8×10¹⁹/cm³, and further preferably 1×10¹⁹/cm³ to 5×10¹⁹/cm³.

The second p-type layer 132 preferably has a thickness of 0.05 μm to 0.2 μm. By setting the thickness of the second p-type layer 132 to not less than 0.05 μm, a desired threshold voltage can be obtained. By setting the thickness of the second p-type layer 132 to not more than 0.2 μm, the increase of on-resistance can be minimized.

The second n-type layer 140 is a Si-doped n-GaN layer deposited on the p-type layer 130. The second n-type layer 140 has a thickness of, for example, 0.2 μm, and a Si concentration of, for example, 3×10¹⁸/cm³.

The trench T1 is formed in a predetermined position on the surface of the second n-type layer 140, and has a depth passing through the second n-type layer 140 and the p-type layer 130 and reaching the first n-type layer 120. The first n-type layer 120 is exposed on the bottom surface of the trench T1. That is, the bottom surface of the trench T1 is under the interface between the first p-type layer 131 and the first n-type layer 120. The first n-type layer 120, the p-type layer 130, and the second n-type layer 140 are exposed on the side surface of the trench T1. The side surface of the p-type layer 130 exposed on the side surface of this trench T1 is a region serving as an FET channel of the first embodiment.

The gate insulating film F1 is formed in a film continuously from the bottom surface, the side surface of the trench T1 to the surface of the second n-type layer 140 (except for the region where a source electrode S1 is formed). The gate insulating film F1 is made of SiO₂. The gate insulating film F1 has a thickness of, for example, 80 nm.

The gate insulating film F1 is not necessarily made of SiO₂, and may be made of Al₂O₃, HfO₂, ZrO₂, ZrON, and others. The gate insulating film F1 is not necessarily a single layer, and may include a plurality of layers, for example, SiO₂/Al₂O₃, and SiO₂/ZrON/Al₂O₃. Here, the symbol “/” means depositing, and A/B means a layered structure in which a layer of A is first formed and a layer of B is then formed. The symbol “/” will be used in the same meaning in the description of materials provided below.

The gate electrode G1 is formed in a film continuously from the bottom surface, the side surface to the top surface of the trench T1 on the gate insulating film F1. The gate electrode G1 is made of TiN.

The recess R1 is formed in a predetermined position on the surface of the second n-type layer 140, and has a depth passing through the second n-type layer 140 and reaching the second p-type layer 132, but not reaching the first p-type layer 131. The second p-type layer 132 is exposed on the bottom surface of the recess R1. The second p-type layer 132 and the second n-type layer 140 are exposed on the side surface of the recess R1. Since the recess R1 is formed by dry etching, etching damage is caused on the bottom surface of recess R1.

The recess R1 may have any depth as long as the second p-type layer 132 is exposed and the first p-type layer 131 is not exposed on the bottom surface of the recess R1. However, the depth of the recess R1 is preferably set so that the thickness H from the bottom surface of the recess R1 to the interface between the second p-type layer 132 and the first p-type layer 131 (i.e., the thickness of the second p-type layer 132 in a region where the second p-type layer 132 is exposed by the recess R1) is not less than 0.05 μm. Also, the distance from the bottom surface of the recess R1 to the interface between the second p-type layer 132 and the second n-type layer 140 may preferably be not less than 0 μm and not larger than 0.15 μm. By setting the depth of the recess R1 to such a depth, the contact resistance between the body electrode B1 and the p-type layer 130 can be sufficiently reduced.

The body electrode B1 is formed on the bottom surface of the recess R1 in contact with the second p-type layer 132 exposed thereon. The body electrode B1 is made of Ni. Also, the body electrode B1 may be made of at least one of Pd, Ni/Pd, other metal alloy, deposited metals, and other material having ohmic contact to p-type semiconductor. Since etching damage exists on the bottom surface of the recess R1, the acceptor concentration of the bottom surface of the recess R1 is reduced. However, the Mg concentration of the second p-type layer 132 subject to etching damage is higher than the Mg concentration of the first p-type layer 131, thereby reducing the contact resistance between the body electrode B1 and the p-type layer 130, i.e., the contact resistance to the second p-type layer 132.

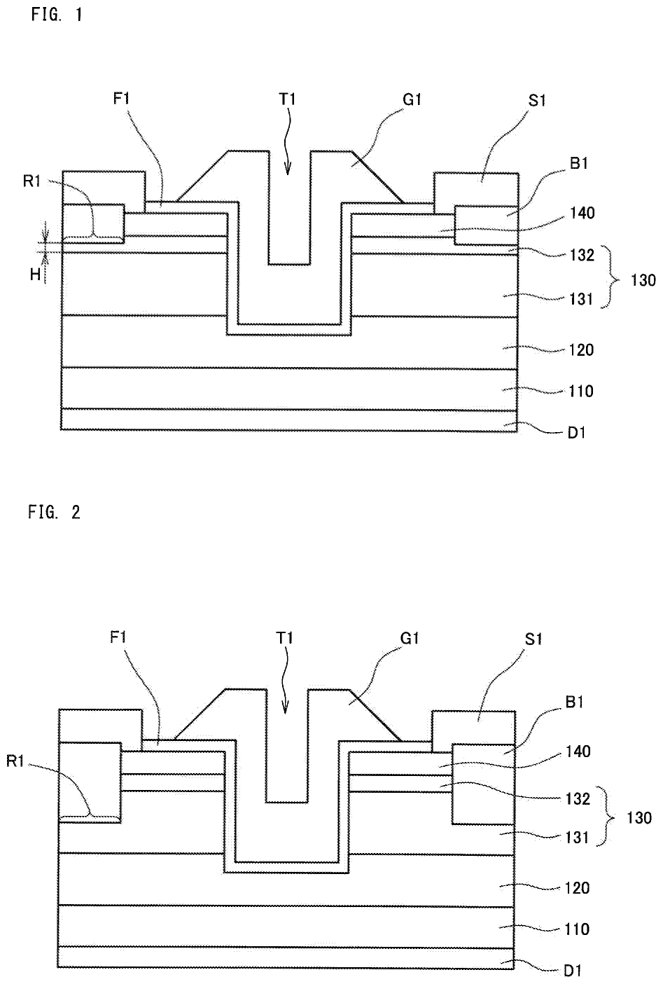

The recess R1 may have a depth reaching the first p-type layer 131, and the body electrode B1 may be formed in contact with the first p-type layer 131 exposed on the bottom surface of the recess R1 (refer to FIG. 2). Even in this case, the on-resistance can be reduced while increasing the threshold voltage as in the first embodiment. However, the body electrode B1 is preferably formed in contact with the second p-type layer 132 having a higher Mg concentration as in the first embodiment to reduce the contact resistance between the body electrode B1 and the p-type layer 130, and increase the avalanche breakdown voltage.

The source electrode S1 is continuously formed on the body electrode B1 and the second n-type layer 140. The source electrode S1 is made of Ti/Al.

The drain electrode D1 is formed on a back side of the substrate 110. The drain electrode D1 is made of Ti/Al which is the same material as that of the source electrode S1.

In the semiconductor device according to the first embodiment, the p-type layer 130 has a two-layer structure of the first p-type layer 131 and the second p-type layer 132 having a Mg concentration higher than the Mg concentration of the p-type layer 131. The Mg concentration of the second p-type layer 132 is 6×10¹⁸/cm³. Therefore, the threshold voltage of the semiconductor device according to the first embodiment can be increased. Even if the Mg concentration of the first p-type layer 131 is reduced, the threshold voltage is not reduced. By setting the Mg concentration of the first p-type layer 131 to less than 6×10¹⁸/cm³, the channel resistance can be reduced. In this way, with the structure of the p-type layer 130 of the first embodiment, the channel resistance can be reduced, that is, the on-resistance can be reduced while increasing the threshold voltage.

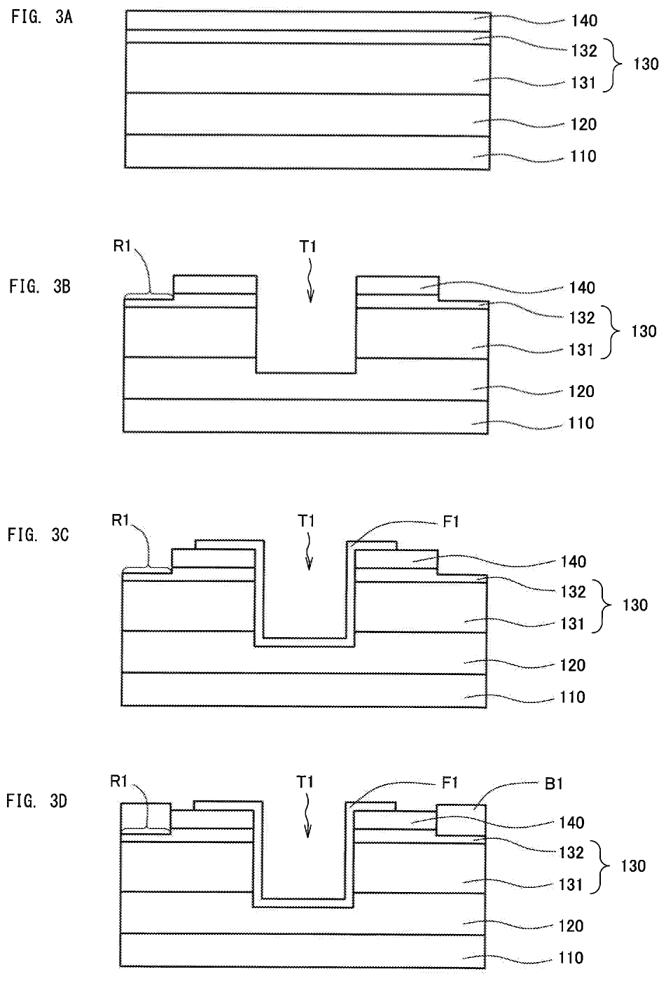

Next will be described processes for producing the semiconductor device according to the first embodiment with reference to FIGS. 3A to 3D.

Firstly, a first n-type layer 120, a first p-type layer 131, a second p-type layer 132, and a second n-type layer 140 are sequentially deposited through MOCVD on a substrate 110 (refer to FIG. 3A). In MOCVD, ammonia is used as a nitrogen source, trimethylgallium (Ga(CH₃)₃:TMG) is used as a Ga source, silane (SiR₄) is used as an n-type dopant gas, and biscyclopentadienylmagnesium (Mg(C₅H₅)₂:CP₂Mg) is used as a p-type dopant gas. Hydrogen is used as a carrier gas. Any crystal growth method other than MOCVD, for example, MBE or CBE may also be employed.

A p-type layer 130 is formed so as to have a two-layer structure of the first p-type layer 131 and the second p-type layer 132 having a Mg concentration higher than the Mg concentration of the first p-type layer 131 and not less than 6×10¹⁸/cm³. The Mg concentration of the first p-type layer 131 is lower than the Mg concentration of the second p-type layer 132. Therefore, the on-resistance can be reduced while increasing the threshold voltage. Moreover, the threshold voltage can be controlled to a desired value by adjusting the Mg concentration of the second p-type layer 132. For example, the threshold voltage can be controlled to achieve normally-off operation (threshold voltage is a value larger 0V, preferably larger than 2V).

Subsequently, a trench T1 and a recess R1 are formed by dry etching predetermined positions on the surface of the second n-type layer 140 (refer to FIG. 3B). After the trench T1 was formed, the recess R1 may be formed. Or after the recess R1 was formed, the trench T1 may be formed. Chlorine-based gas such as Cl₂, SiCl₄, and BCl₃ is used for dry etching. Any method such as ICP etching may be used for dry etching. Through dry etching, etching damage is caused on the side surface and the bottom surface of the trench T1 and the recess R1. In a vertical FET having a GaN semiconductor layer, like the semiconductor device according to the first embodiment, a p-type region, i.e., a body layer (p-type layer 130) is difficult to be formed by ion implantation. Therefore, after a layer structure including the p-type layer 130 is deposited by crystal growth, a trench T1 is formed by dry etching to form a trench gate structure.

After the formation of the trench T1 and the recess R1, the layer damaged by dry etching may be removed by wet etching the side surface. Wet etching solution such as TMAH (Tetramethylammonium hydroxide), NaOH (sodium hydroxide), KOH (potassium hydroxide), and H₃PO₄ (phosphoric acid) may be used. Since the bottom surface of the trench T1 and the recess R1 is a c-plane of GaN, they are hardly etched, and the damaged layer is not sufficiently removed. As a result, etching damage remains. Therefore, even if the damaged layer is removed by wet etching, the threshold voltage is not sufficiently restored.

Next, the p-type layer 130 attains p-type conduction by heating in a nitrogen atmosphere. Hydrogen efficiently escapes from the p-type layer 130 exposed on the bottom surface of the recess R1 or the side surface of the trench T1, thereby efficiently activating Mg in the p-type layer 130.

A SiO₂ gate insulating film F1 is formed by ALD continuously on the bottom surface and the side surface of the trench T1, and the surface of the second n-type layer 140 (refer to FIG. 3C). By using ALD, the gate insulating film F1 has a uniform thickness even if there is a step due to the trench T1. In the first embodiment, the gate insulating film F1 is formed by ALD because of its high step coverage. However, the gate insulating film F1 may be formed by sputtering or CVD.

A body electrode B1 is formed by lift-off method on the bottom surface of the recess R1 (refer to FIG. 3D). Since the recess R1 is formed by dry etching, etching damage is caused on the bottom surface of the recess R1. Etching damage reduces the acceptor concentration of the bottom surface of the recess R1. However, the Mg concentration of the second p-type layer 132 subject to etching damage is higher than the Mg concentration of the first p-type layer 131, thereby compensating the reduction of the acceptor concentration and reducing the contact resistance between the body electrode B1 and the p-type layer 130, i.e., the second p-type layer 132.

A source electrode S1 and a gate electrode G1 are formed by lift-off method, and further a drain electrode D1 is formed on an entire back side of the substrate 110. In this way, the semiconductor device according to the first embodiment shown in FIG. 1 is produced.

### Second Embodiment

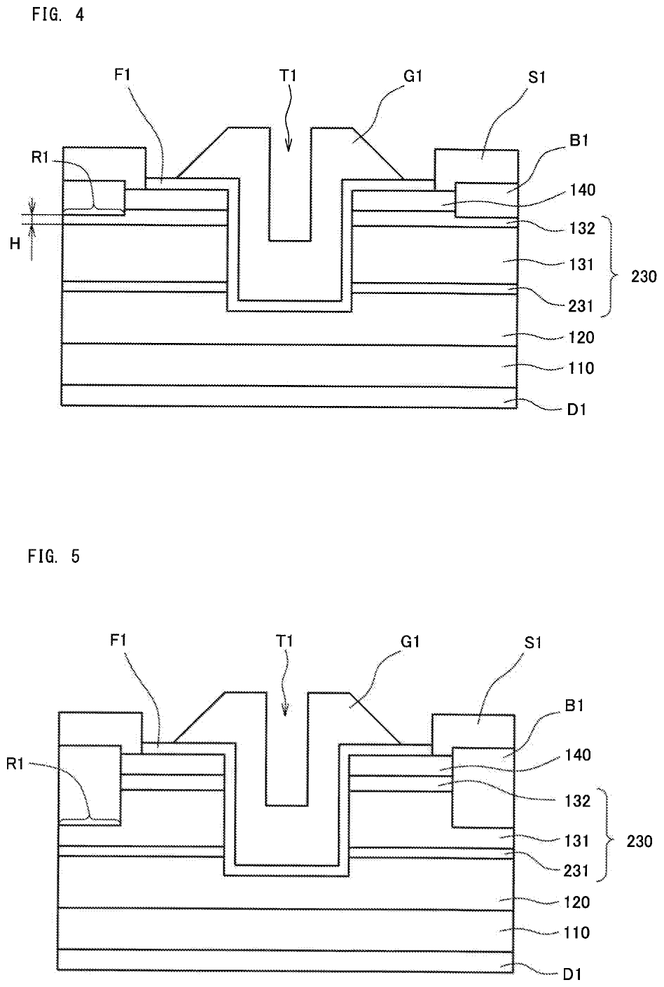

FIG. 4 shows the structure of a semiconductor device according to a second embodiment. The semiconductor device according to the second embodiment has a structure in which a third p-type layer 231 is further formed between the first n-type layer 120 and the first p-type layer 131 in the semiconductor device according to the first embodiment. That is, the p-type layer 130 is substituted by a p-type layer 230 having a three-layer structure in which a third p-type layer 231, a first p-type layer 131, and a second p-type layer 132 are sequentially deposited. Other structure is the same as that of the semiconductor device according to the first embodiment.

The third p-type layer 231 is the bottom layer of a plurality of layers constituting the p-type layer 230, and is in contact with the first n-type layer 120. The third p-type layer 231 has a Mg concentration higher than the Mg concentration of the first p-type layer 131 and not more than the Mg concentration of the second p-type layer 132. By making the Mg concentration of the third p-type layer 231 higher than the Mg concentration of the first p-type layer 131, the expansion of the depletion layer to the p-type layer 230 can be minimized, and the deterioration of the gate insulating film F1 can be suppressed. By making the Mg concentration of the third p-type layer 231 not more than the Mg concentration of the second p-type layer 132, the increase of channel resistance and the increase of on-resistance can be suppressed. The third p-type layer 231 has a thickness of, for example, 0.1 μm, and a Mg concentration of, for example, 6×10¹⁸/cm³.

The third p-type layer 231 preferably has a thickness of 0.1 μm to 0.2 μm. As long as the thickness is within this range, both the deterioration of the gate insulating film F1 and the increase of on-resistance can be efficiently suppressed.

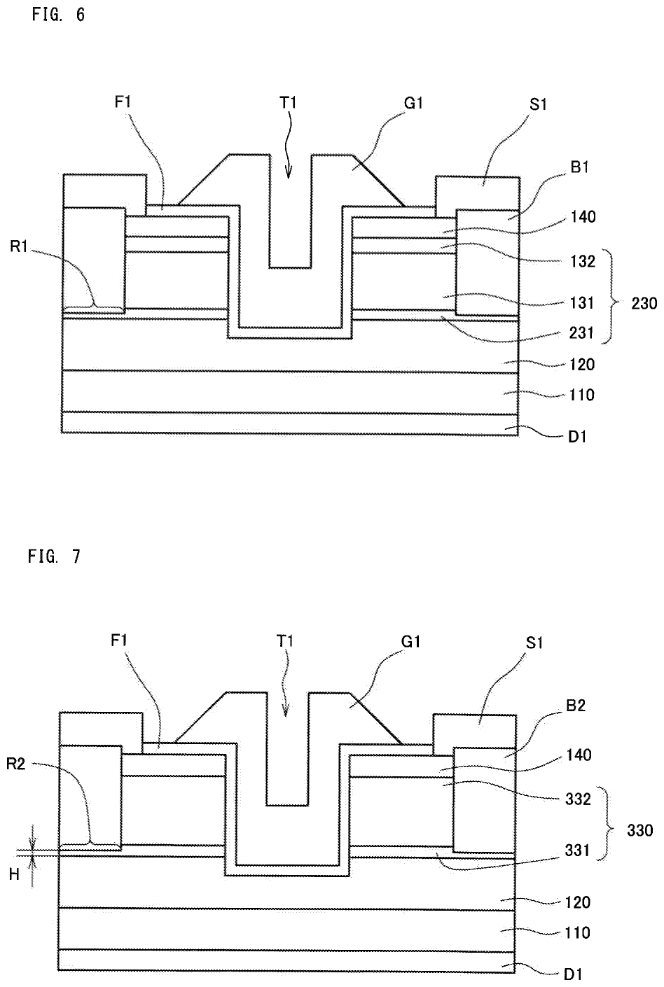

In the second embodiment, the recess R1 has a depth reaching the second p-type layer 132, and the body electrode B1 is formed in contact with the second p-type layer 132. However, the body electrode B1 may be formed in contact with the first p-type layer 131 (refer to FIG. 5) or in contact with the third p-type layer 231 (refer to FIG. 6). To reduce the contact resistance between the body electrode B1 and the p-type layer 130 and increase the avalanche breakdown voltage, the body electrode B1 is preferably formed in contact with the second p-type layer 132 having the highest Mg concentration.

Thus, in the second embodiment, the on-resistance can be reduced while increasing the threshold voltage as in the first embodiment. Moreover, the deterioration of the gate insulating film F1 can be suppressed.

### Third Embodiment

FIG. 7 shows the structure of a semiconductor device according a third embodiment. In the semiconductor device according to the third embodiment, the p-type layer 130, the recess R1, and the body electrode B1 in the first embodiment are respectively substituted by a p-type layer 330, a recess R2, and a body electrode 32. Other structure is the same as that of the semiconductor device according to the first embodiment.

The p-type layer 330 is a Mg-doped p-GaN layer deposited on the first n-type layer 120. The p-type layer 330 has a two-layer structure in which a first p-type layer 331 and a second p-type layer 332 are sequentially deposited.

The first p-type layer 331 has a Mg concentration higher than the Mg concentration of the second p-type layer 332, and is in contact with the first n-type layer 120. The first p-type layer 331 is provided to increase the threshold voltage. The first p-type layer 331 is provided to minimize the expansion of the depletion layer to the p-type layer 330, and to suppress the deterioration of the gate insulating film F1. In other words, the first p-type layer 331 in the third embodiment is a layer having both functions of the second p-type layer 132 in the first embodiment and the third p-type layer 231 in the second embodiment. The first p-type layer 331 has a thickness of, for example, 0.1 μm, and a Mg concentration of, for example, 6×10¹⁸/cm³.

The Mg concentration of the first p-type layer 331 is not limited to the above value, and may be not less than 6×10¹⁸/cm³. As long as the first p-type layer 331 has a Mg concentration of not less than 6×10¹⁸/cm³, the threshold voltage is not affected even if the second p-type layer 332 has a Mg concentration of less than 6×10¹⁸/cm³. The threshold voltage can almost be determined by the Mg concentration of the first p-type layer 331, and the threshold voltage can be increased. Therefore, normally off operation can be more reliably achieved. Moreover, the expansion of the depletion layer to the p-type layer 330 can be minimized, thereby suppressing the deterioration of the gate insulating film F1. However, the first p-type layer 331 preferably has a Mg concentration of not more than 1×10²⁰/cm³. Because the Mg concentration of the second p-type layer 332 is lower than that of the first p-type layer 331, deterioration in crystal quality or reduction in electron concentration of the second n-type layer 140 formed on the second p-type layer 332 can be suppressed. The Mg concentration of the first p-type layer 331 is more preferably 8×10¹⁸/cm³ to 8×10¹⁹/cm³, and further preferably 1×10¹⁹/cm³ to 5×10¹⁹/cm³.

The first p-type layer 331 preferably has a thickness of 0.05 μm to 0.2 μm. By setting the thickness of the first p-type layer 331 to not less than 0.05 μm, a desired threshold voltage can be obtained, and the expansion of the depletion layer to the p-type layer 330 can be suppressed, thereby suppressing the deterioration of the gate insulating film F1. Moreover, by setting the thickness of the first p-type layer 331 to not more than 0.2 μm, the increase of on-resistance can be minimized.

The second p-type layer 332 has a Mg concentration lower than the Mg concentration of the first p-type layer 331. The second p-type layer 332 has a thickness of, for example, 0.6 μm, and a Mg concentration of, for example, 2×10¹⁸/cm³. By reducing the Mg concentration of the second p-type layer 332 of a plurality of layers constituting the p-type layer 330, the increase of channel resistance can be suppressed, and the increase of on-resistance can be suppressed.

The second p-type layer 332 may have any Mg concentration as long as it is not more than 6×10¹⁸/cm³. However, the second p-type layer 332 preferably has a Mg concentration of not more than 3×10¹⁸/cm³, thereby further reducing the on-resistance.

The recess R2 is formed in a predetermined position on the surface of the second n-type layer 140, and has a depth passing through the second n-type layer 140 and the second p-type layer 332 and reaching the first p-type layer 331, but not reaching the first n-type layer 120. The first p-type layer 331 is exposed on the bottom surface of the recess R2. The first p-type layer 331, the second p-type layer 332, and the second n-type layer 140 are exposed on the side surface of the recess R2. Since the recess R2 is formed by dry etching, etching damage is caused on the bottom surface of the recess R2.

The recess R2 may have any depth as long as the first p-type layer 331 is exposed and the first n-type layer 120 is not exposed on the bottom surface of the recess R2. However, the depth of the recess R2 is preferably set so that the thickness H from the bottom surface of the recess R2 to the interface between the first p-type layer 331 and the first n-type layer 120 (i.e., the thickness of the first p-type layer 331 in a region where the first p-type layer 331 is exposed by the recess R2) is not less than 0.05 μm. Also, the distance from the bottom surface of the recess R2 to the interface between the second p-type layer 332 and the first p-type layer 331 may preferably be not less than 0 μm and not larger than 0.15 μm. By setting the depth of the recess R2 to such a depth, the contact resistance between the body electrode B2 and the p-type layer 330 can be sufficiently reduced.

The body electrode B2 is formed on the bottom surface of the recess R2 in contact with the first p-type layer 331 exposed thereon. The body electrode B2 is made of Ni. Since etching damage exists on the bottom surface of the recess R2, the acceptor concentration of the bottom surface of the recess R2 is reduced. However, the Mg concentration of the first p-type layer 331 subject to etching damage is higher than the Mg concentration of the second p-type layer 332, thereby reducing the contact resistance between the body electrode B2 and the p-type layer 130.

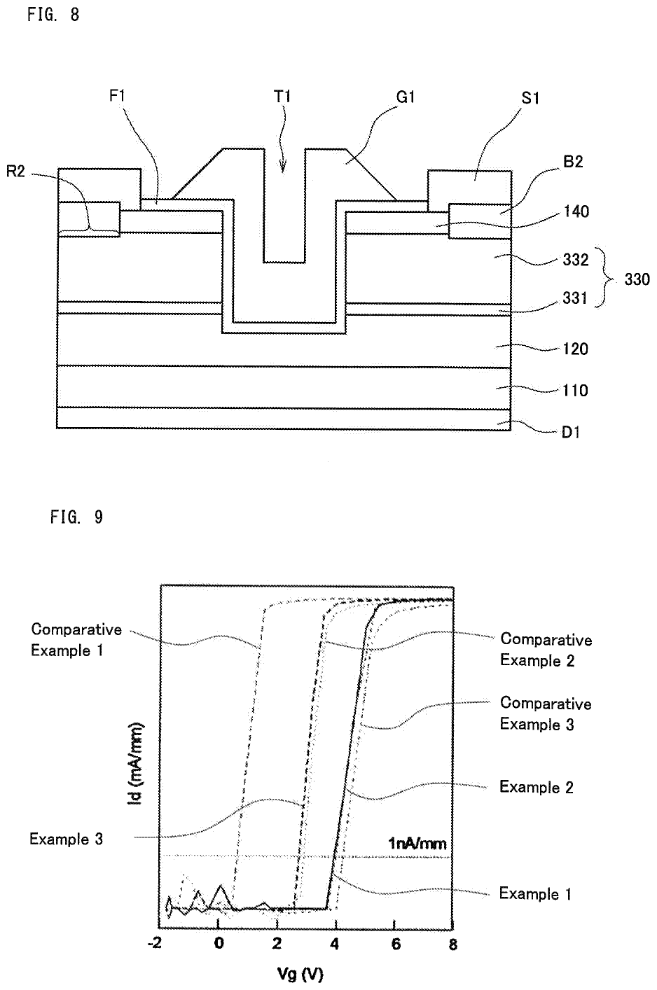

The recess R2 may have a depth reaching the second p-type layer 332, and the body electrode B2 may be formed in contact with the second p-type layer 332 exposed on the bottom surface of the recess R2 (refer to FIG. 8). Even in this case, the on-resistance can be reduced while increasing the threshold voltage as in the third embodiment. However, the body electrode B2 is preferably formed in contact with the first p-type layer 331 having a higher Mg concentration as in the third embodiment to reduce the contact resistance between the body electrode B2 and the p-type layer 330, and increase the avalanche breakdown voltage.

In the third embodiment, the on-resistance can be reduced while increasing the threshold voltage as in the second embodiment. Moreover, the deterioration of the gate insulating film F1 can be suppressed.

Next will be described the experimental results of the semiconductor devices according to the first, second, and. third embodiments.

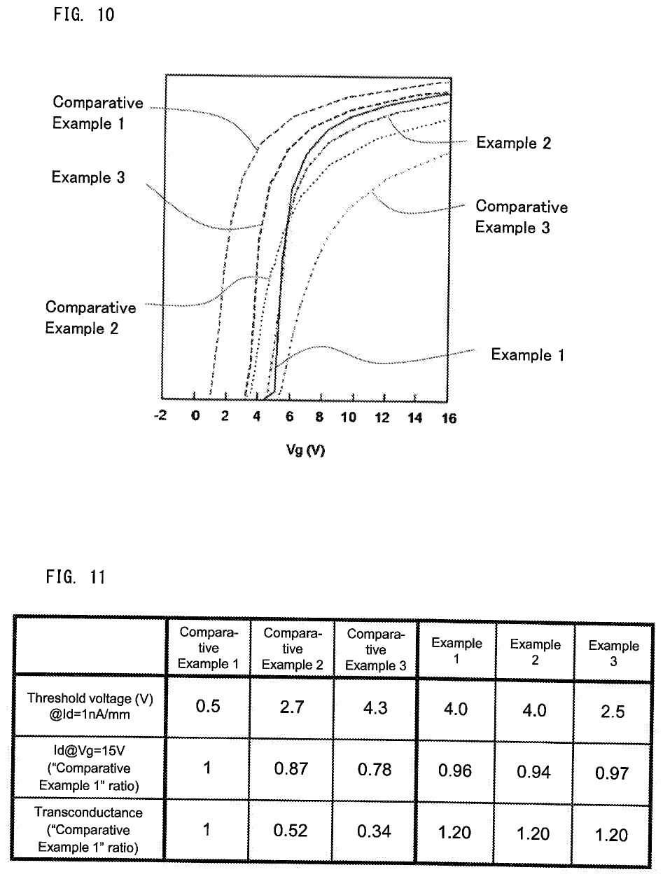

FIGS. 9 and 10 are graphs showing the Id-Vg characteristic measurement results of semiconductor devices of Examples 1 to 3 and Comparative Examples 1 to 3. FIG. 9 shows a logarithmic plot of drain current Id on the vertical axis, and FIG. 10 shows a linear plot of drain current Id on the vertical axis. Drain voltage Vd was set to 0.5 V. In Comparative Examples 1 to 3, the p-type layers 130, 230, and 330 are single layers, and have different Mg concentrations. Other structure is the same as those of Examples 1 to 3. The Mg concentration of the p-type layer is 2×10¹⁸/cm³ in Comparative Example 1, 6×10¹⁸/cm³ in Comparative Example 2, and 1×10¹⁹/cm³ in Comparative Example 3.

FIG. 11 is a table showing the results obtained by measured threshold voltage, drain current Id, and transconductance of semiconductor devices of Examples 1 to 3 and Comparative Examples 1 to 3. Threshold voltage is a gate voltage Vg when the drain current Id is 1 nA/mm. Drain current Id in the table shows drain current Id when Vg is 15V, and is indicated by a value relative to drain current Id of Comparative Example 1 set as 1. Transconductance is indicated by a value relative to transconductance of Comparative Example 1 set as 1.

As shown in FIGS. 9 to 11, in the semiconductor devices of Examples 1 to 3, high threshold voltage was achieved while minimizing the reduction of drain current Id, i.e., minimizing the increase of on-resistance. As shown in FIG. 11, in the semiconductor devices of Examples 1 to 3, transconductance was increased more than those of Comparative Examples 1 to 3.

### (Variation)

The p-type layer has a two-layer structure in the first and third embodiments, and has a three-layer structure in the second embodiment. However, in the present invention, the p-type layer may have any number of layers as long as the p-type layer has two or more layers. The layer having a Mg concentration of not less than 6×10¹⁸/cm³ of a plurality of layers constituting the p-type layer is the top layer in the first and second embodiments, and the bottom layer in the third embodiment. However, in the present invention, the layer having a Mg concentration of not less than 6×10¹⁸/cm³ is at any position in the layer structure. In other words, in the present invention, the p-type layer may have a plurality of layers wherein the layer having the highest Mg concentration (high concentration layer) has a Mg concentration of not less than 6×10¹⁸/cm³, and other layers have a Mg concentration of less than 6×10¹⁸/cm³.

The first to third embodiments are a GaN semiconductor device. The present invention is not limited to a GaN semiconductor device, but is applicable to a Group III nitride semiconductor device. The present invention is also applicable to a gallium oxide-based semiconductor device. A gallium oxide-based semiconductor is an oxide semiconductor of gallium oxide (Ga₂O₃) or gallium oxide with Ga site partially substituted by Al or In. For Group III oxide semiconductor or gallium oxide-based semiconductor, a p-type region is difficult to be formed by ion implantation as in GaN semiconductor. Thus, the present invention is preferable.

The embodiments were described using a field effect transistor (FET). However, the present invention can also be implemented in a transistor having a trench type insulating gate structure such as IGBT.

In the first to third embodiments, the p-type region formed by ion implantation does not exist in an active region, i.e., channel, but the p-type region formed by ion implantation may exist in the terminal end region of the channel.

The semiconductor device of the present invention can be employed as a power device.

What is claimed is:

1. A method for producing a semiconductor device as a transistor with a trench gate structure, having a semiconductor layer comprising Group III nitride semiconductor or gallium oxide-based semiconductor formed by sequentially deposing a first n-type layer, a p-type layer, and a second n-type layer, wherein the p-type layer has a plurality of layers, the layer having the highest acceptor concentration of those layers is defined as a high concentration layer, the high concentration layer has an acceptor concentration of not less than 6×10¹⁸/cm³, the layers other than the high concentration layer of a plurality of layers of the p-type layer has an acceptor concentration of less than 6×10¹⁸/cm³, and the threshold voltage is controlled to a desired value by the acceptor concentration of the high concentration layer.

2. The method for producing the semiconductor device according to claim 1, wherein the high concentration layer has a thickness of 0.05 μm to 0.2 μm.

3. The method for producing the semiconductor device according to claim 1, wherein the high concentration layer has an acceptor concentration of not more than 1×10²⁰/cm³.

4. The method for producing the semiconductor device according to claim 3, wherein the high concentration layer has a thickness of 0.05 μm to 0.2 μm.

5. The method for producing the semiconductor device according to claim 1, wherein a total thickness of the layers other than the high concentration layer of a plurality of layers of the p-type layer is 0.5 μm to 1.5 μm.

6. The method for producing the semiconductor device according to claim 1, wherein the high concentration layer is the top layer of the p-type layer.

7. The method for producing the semiconductor device according to claim 1, wherein the high concentration layer is the bottom layer of the p-type layer.

8. The method for producing the semiconductor device according to claim 6, wherein the p-type layer has a layer in contact with the first n-type layer and having an acceptor concentration higher than the acceptor concentration of the layers other than the high concentration layer and not more than 6×10¹⁸/cm³.

9. The method for producing the semiconductor device according to claim 2, wherein the high concentration layer has an acceptor concentration of not more than 1×10²⁰/cm³ and not less than 6×10¹⁸/cm³.
